(19) United States
(12) Patent Application Publication
(10) Pub. No.: US 2026/0150449 A1
(43) Pub. Date: May 28, 2026

(54) LIGHT-EMITTING DIODES WITH METAL PILLARS FOR PLUGGED SUBSTRATES

(71) Applicant: CreeLED, Inc., Durham, NC (US)

(72) Inventors: David Suich, Durham, NC (US); Michael Check, Holly Springs, NC (US); Joseph G. Sokol, Durham, NC (US); Robert Wilcox, Rolesville, NC (US); Andre Pertuit, Raleigh, NC (US); Colin Blakely, Raleigh, NC (US)

(21) Appl. No.: 18/958,652

(22) Filed: Nov. 25, 2024

(51) Int. Cl. H01L 33/62; H01L 33/48

(52) U.S. Cl. CPC H10H 20/857; H10H 20/8506; H10H 20/0364

(57) ABSTRACT

Light-emitting devices, and more particularly, LED chips that have pillars or pillar-like structures for plugged substrates are disclosed. Pillars can be formed of metal that plug into hollow vias of a substrate, enabling the LED chip to have electrical contact with a submount on which the substrate is mounted. The pillars can facilitate easier mounting of the LED chips to the submount in a surface mount device (SMD) context. The pillars can also serve as alignment pins to improve the die attach process. The substrate can include back-side metal contacts to facilitate the electrical contact between the pillars and the submount. In other embodiments, the hollow vias can extend all the way through the substrate allowing the pillars to make direct electrical contact with the submount.

### FIELD OF THE DISCLOSURE

The present disclosure relates to light-emitting diode chips with metal pillars for plugged substrates.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays and lighting devices for general illumination.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly, to LED chips that have pillars or pillar-like structures for plugged substrates. Pillars can be formed of metal that plug into hollow vias of a substrate, enabling the LED chip to have electrical contact with a submount on which the substrate is mounted. The pillars can facilitate easier mounting of the LED chips to the submount in a surface mount device (SMD) context. The pillars can also serve as alignment pins to improve the die attach process. The substrate can include back-side metal contacts to facilitate the electrical contact between the pillars and the submount. In other embodiments, the hollow vias can extend all the way through the substrate allowing the pillars to make direct electrical contact with the submount.

In one aspect, an LED package includes a submount, a substrate bonded to the submount, wherein the substrate comprises a hollow via. The LED package can also include an LED chip mounted to the substrate, wherein the LED chip comprises a conductive layer bonded to an active LED structure, and a pillar formed on the conductive layer, wherein the pillar extends through the hollow via of the substrate and is electrically coupled to the submount. In an embodiment, the hollow via extends entirely through the substrate and the pillar is in direct contact with a trace on the submount. In an embodiment, the hollow via extends partially through the substrate, and the pillar is in contact with a conductive pad on the substrate, wherein the conductive pad is in contact with the submount. In an embodiment, the LED chip comprises a plurality of pillars formed on the conductive layer, wherein each pillar is configured to extend through a respective hollow via of the substrate. In an embodiment, the plurality of pillars are arranged asymmetrically. In an embodiment, the LED chip is flip-chip mounted to the substrate, and wherein the conductive layer comprises a plurality of conductive pads, each with one or more pillars mounted thereon. In an embodiment, the LED chip is a vertical geometry chip. In an embodiment, the pillar comprises copper. In an embodiment, a tip of the pillar is terminated in a metallic alloy. In an embodiment, the pillar has a height between 10 μm and 200 μm and a diameter between 10 μm and 100 μm. In an embodiment, the hollow via of the substrate comprises an electrically conductive adhesive.

In one aspect, an LED chip includes an active LED structure, a conductive layer bonded to the active LED structure, and a pillar formed on the conductive layer, wherein the pillar is conductive and is configured to extend through a hollow via of a substrate to electrically couple to a submount structure. In an embodiment, there are a plurality of pillars formed on the conductive layer, wherein each pillar is configured to extend through a respective hollow via of the substrate. In an embodiment, the plurality of pillars are arranged asymmetrically. In an embodiment, the LED chip is flip-chip mounted to the substrate, and wherein the conductive layer comprises a plurality of conductive pads, each with one or more pillars formed thereon. In an embodiment, the LED chip is a vertical geometry chip. In an embodiment, the pillar comprises copper. In an embodiment, a tip of the pillar is terminated in a metallic alloy. In an embodiment, the pillar has a height between 10 μm and 200 μm and a diameter between 10 μm and 100 μm.

In another aspect, a method for fabricating an LED package includes forming a pillar on an LED chip, wherein the pillar is conductive and is formed on a conductive layer. The method also includes forming a hollow via in a substrate and mounting the substrate on a submount. The method also includes mounting the LED chip on the substrate, wherein the pillar extends into the hollow via to electrically couple with the submount.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a perspective view of a light-emitting diode (LED) package of a submount, substrate, and an LED chip with pillars according to principles of the disclosure.

FIG. 2 is a perspective view of an LED chip with pillars that tipped in a metal alloy according to principles of the disclosure.

FIG. 3 is a perspective view of an LED chip with asymmetric pillars according to principles of the disclosure.

FIG. 4 is a perspective view of a vertical geometry LED chip with pillars according to principles of the disclosure.

FIG. 5 is a perspective view of a substrate with thermal paste or solder according to principles of the disclosure.

FIG. 6 is a perspective view of a light-emitting diode (LED) package of a submount, substrate with completely hollow vias extending throughout, and an LED chip with pillars according to principles of the disclosure.

FIG. 7 is a flowchart of a method for fabricating an LED package according to principles of the disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly, to LED chips that have pillars or pillar-like structures for plugged substrates. Pillars can be formed of metal that plug into hollow vias of a substrate, enabling the LED chip to have electrical contact with a submount on which the substrate is mounted. The pillars can facilitate easier mounting of the LED chips to the submount it easier to mount the LED chips in a surface mount device (SMD) context. The pillars can also serve as alignment pins to improve the die attach process. The substrate can include back-side metal contacts to facilitate the electrical contact between the pillars and the submount. In other embodiments, the hollow vias can extend all the way through the substrate allowing the pillars to make direct electrical contact with the submount.

Before delving into specific details for aspects of the present disclosure, an overview of various elements that may be included in exemplary LED packages is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, and/or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc.

Lumiphoric materials as described herein may be or include one or more of a phosphor, a scintillator, a lumiphoric ink, a quantum dot material, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a submount.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Aspects of the present disclosure are also well suited for embodiments with flexible substrates. By way of example, a flexible submount may comprise a polyimide, a polyethylene terephthalate (PET), and the like with electrically conductive traces. Flexible submounts allow improved bonding in a conformal manner to other surfaces that may not be entirely planar.

Encapsulant materials, such as silicone, epoxy, or polymethyl methacrylate (PMMA), among others, may be formed to encapsulate the LED chips over a submount. In certain embodiments, one or more lumiphoric materials, such as phosphor particles, may be integrated or otherwise embedded within the encapsulant material. Moreover, encapsulant materials may be shaped to form single lens structures and/or multiple lens structures in a single LED package.

Light-altering materials may be arranged within LED packages, such as along submount surfaces, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO2), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Aspects of the present disclosure relate to LED chips with pillars, substrates with hollow vias, and methods of fabrication thereof. The LED chips, either flip-chip mounted, or vertical geometry LED chips can have pillars that enable them to be plugged into substrates with hollow vias to assist in mounting the LED chips to the substrates in a surface mount device (SMD) context, where the pillars make electrical contact with the submount beneath the substrate, either directly, or via conductive structures in the substrate. The pillars can serve as built-in alignment pins to make it easier to align the LED chips above the substrate and submount and assist in attaching the LED chips to the substrate and submount.

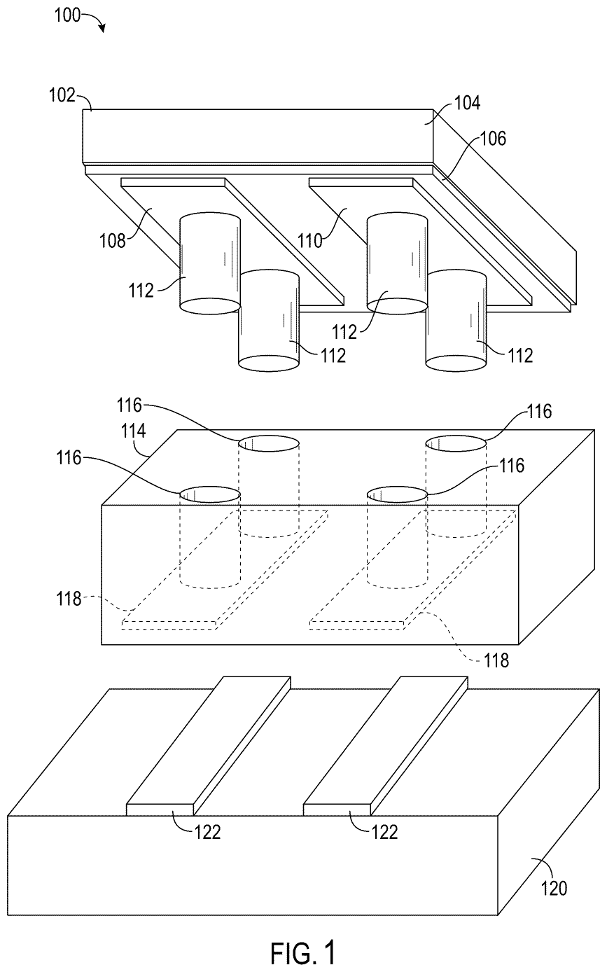

Turning to FIG. 1, illustrated is a perspective view of a light-emitting diode (LED) package of a submount, substrate, and an LED chip with pillars according to principles of the disclosure.

The LED package 100 depicted in FIG. 1 includes an LED chip 102, a substrate 114, and a submount 120. The LED chip 102 can include one or more pillars 112 that slot into hollow vias 116 in the substrate 114, in order to make electrical contact with traces 122 on the submount 120.

The substrate 114 can include conductive pads 118 on the backside of the substrate 114 that contact the pillars 112 and the traces 122 on the submount 120. The conductive pads 118 can be metal and partially extend into the hollow vias 116 to contact the tips of the pillars 112.

In an embodiment, the substrate 114 can be mounted to the submount via an adhesive or solder. In other embodiments, the conductive pads 118 can be soldered to the traces 122 on the submount 120. In other embodiments, the encapsulant materials may be formed to encapsulate the LED chip 102 over the substrate 114 and the submount 120.

In an embodiment, the substrate 114 can be comprised of ceramic materials such as aluminum oxide or alumina, AlN, or organic insulators like polyimide (PI) and polyphthalamide (PPA). The submount 120 may comprise a printed circuit board (PCB), sapphire, Si, or any other suitable material.

The hollow vias 116 can be formed via etching that may include laser etching, plasma etching, chemical etching, or mechanical etching (e.g., sandblasting, CO₂ blasting, punch outs etc.).

Likewise, the pillars 112 can be formed via etching using one of the aforementioned techniques after depositing copper or other metal. The pillars may be comprised of copper. In some embodiments, the pillars may be comprised of a ceramic or silicate material and also be plated with various metals including one or more of copper, titanium, silver, gold, tin, or nickel. In various embodiments, the pillars 112 may be a height between 10 μm and 200 μm and a diameter between 10 μm and 100 μm. The pillars 112 may also be formed via an electroplating process where a seed layer is deposited and photolithography process defines where the pillars grow. After the formation of the pillars 112, the photographic mask is removed, and the initial seed layer is removed via etching.

In an embodiment, the LED chip 102 can include a substrate 104 that has an epitaxial layer 106 grown on the substrate 104. The pillars 112 can be formed on a conductive layer (e.g., conductive pads 108 or 110 that are the anode and cathode for the LED chip 102). In the embodiment shown in FIG. 1, LED chip 102 is a flip-chip embodiment, and the substrate 104 may form a primary light-emitting surface of the LED chip 102.

In an embodiment, the pillars 112 can serve as alignment pins to facilitate the die attach process of attaching the LED chip 102 to the substrate 114. The pillars 112 and hollow vias 116 in the substrate 114 can be arranged in a predefined pattern so that only a correct orientation of the LED chip 102 with respect to the substrate 114 will enable the LED chip 102 to be inserted into the substrate 114. In an embodiment, the pillars 112 can also facilitate thermal energy transfer from the LED chip 102 to the substrate 114 and the submount 120. FIG. 1 is provided in the context of two pillars 112 for each conductive pad 108 and 110. The principles of the present disclosure are applicable to other numbers of pillars 112 for each conductive pad 108 and 110, such as three or more pillars 112 for each conductive pad 108 and 110, or a single pillar 112 for each conductive pad 108 and 110.

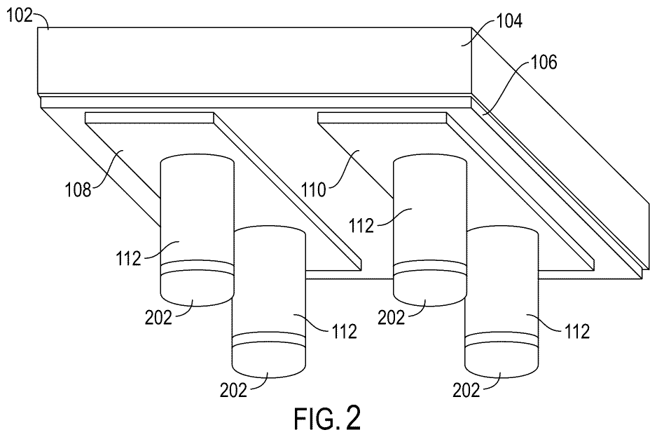

Turning to FIG. 2, illustrated is a perspective view of an LED chip 102 with pillars that tipped in a metal alloy according to principles of the disclosure.

In an embodiment, while the pillars 112 are copper or copper plated, the tips 202 of the pillars 112 can be terminated in one or more metal alloys in the form of a solder to improve electrical and physical connection of the LED chip 102 to the substrate 114 and/or submount 120. For example, the tips 202 can include a lead free solder such as SAC (Sn—Ag—Cu—Tin Silver Copper) which is a lead free solder alloy commonly used for electronic solder in surface mount technology assembly as it is near eutectic, with good thermal energy properties, strength and wettability. In other embodiments, other termination alloys could be used, including an alloy comprising bismuth and silver.

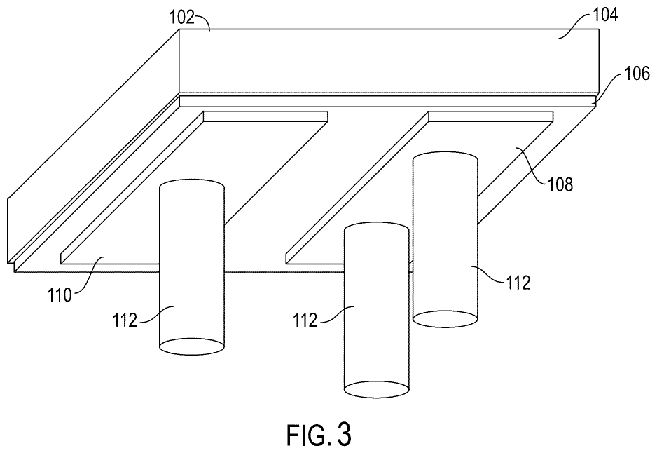

FIG. 3 illustrates a perspective view of an LED chip 102 with asymmetric pillars according to principles of the disclosure. The embodiment of LED chip 102 in FIG. 3 can be compared for example with the embodiment in FIG. 1, where the LED chip includes 2 pillars 112 each on conductive pads 108 and 110.

By contrast in FIG. 3, conductive pad 110 can include a single pillar 112 whilst conductive pad 108 includes two pillars 112. In other embodiments, the conductive pads 110 and 108 can include any numbers of pillars 112. In an embodiment, having an asymmetric number of pillars (e.g., conductive pads 110 and 108 having different numbers of pillars 112 thereon) can allow the pillars 112 to serve as alignment guides to ensure a predefined orientation and position of the LED chip 102 with respect to the substrate 114.

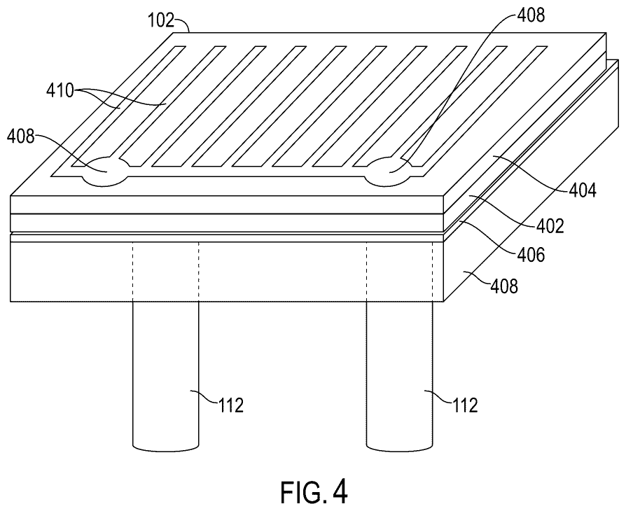

FIG. 4 is a perspective view of a vertical geometry LED chip with pillars according to principles of the disclosure. While applicable to all types of LED chip 102, the embodiments depicted in FIGS. 1-3 are flip-chip mounted LED chips. In the embodiment shown in FIG. 4, however, the techniques disclosed herein of having pillars on the LED chip 102 are shown in the context of a vertical geometry chip.

LED chip 102 in FIG. 4 includes a conductive substrate 408 with the pillars 112 attached thereto. On the other side of the conductive substrate 408 is a metal bonding layer 406, and an N-epitaxial layer 402 and a P-epitaxial layer 404 that serve as the active LED structure of the LED chip 102 that emits light. The pillars 112 on the bottom of the LED chip 102 can be attached to a common conductive pad (e.g., conductive pad 108 and 110). The other electrical connection may be may to a top of the LED chip 102 by way of a wire bond connection to one or more contact pads 408. In certain embodiments, the one or more contact pads 408 may be continuous with one or more contact fingers 410, or contact extensions, that provide increased current spreading. In certain embodiments, the order of the N-epitaxial layer 402 and the P-epitaxial layer 404 may be reversed such that the contact pads 408 and/or contact fingers 410 are on the P-epitaxial layer 404.

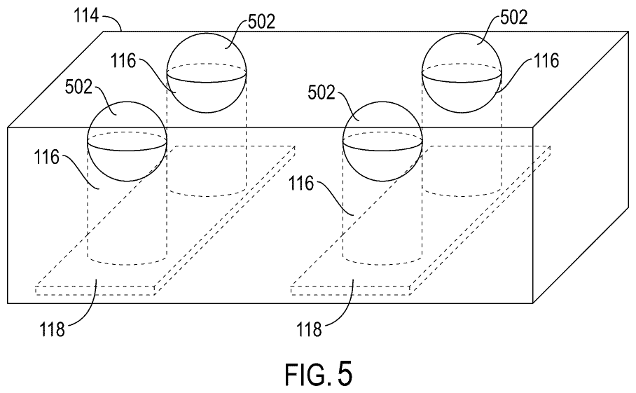

FIG. 5 is a perspective view of a substrate with thermal paste or solder according to principles of the disclosure.

In an embodiment, the hollow vias 116 in the substrate 114 can include an electrically conductive adhesive 502 to ensure that electrical contact is made between the pillars 112 and the conductive pads 118 on the backside of the substrate 114. In an embodiment, the electrically conductive adhesive can be a solder. The electrically conductive adhesive 502 can be placed inside the hollow vias 116 and can improve contact between the conductive pads 118 and the pillars 112 by filling in any airgaps. The electrically conductive adhesive 502 can also facilitate transferring thermal energy from the LED chip 102 and the pillars 112 to the substrate 114.

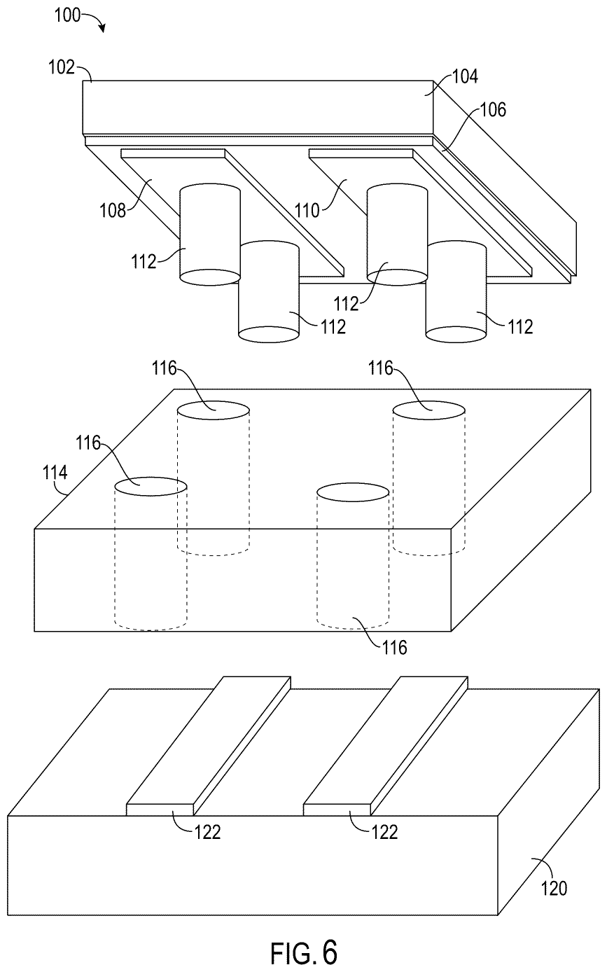

In the embodiment shown in FIG. 6, where there are no conductive pads 118, and the substrate 114 has hollow vias 116 that extend entirely through the substrate 114, the electrically conductive adhesive 502 can be present in order to facilitate electrical contact between the pillars 112 and the traces 122 on the submount 120. In such an embodiment, the electrically conductive adhesive 502 can also provide facilitate thermal energy transfer from the pillars 112 to the substrate 114 and the submount 120.

FIG. 6 is a perspective view of a light-emitting diode (LED) package 100 of a submount 120, substrate 114 with completely hollow vias 116 extending throughout, and an LED chip 102 with pillars 112 according to principles of the disclosure. In the embodiment shown in FIG. 6, the hollow vias 116 extend entirely through the substrate 114, and the substrate 114 does not include the conductive pads 118 on the backside of the substrate 114. In this embodiment, the pillars 112 make electrical contact directly with the traces 122 on the submount 120 (or via the electrically conductive adhesive 502).

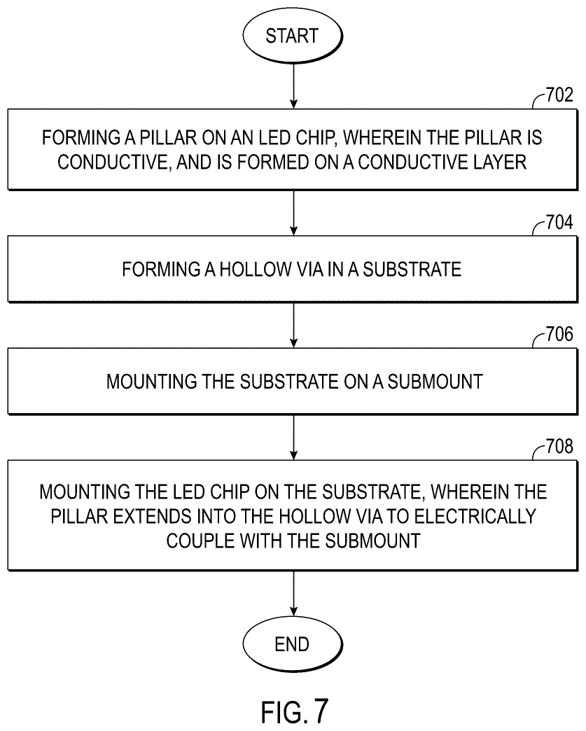

FIG. 7 is a flowchart of a method for fabricating an LED package according to principles of the disclosure.

In an embodiment, the method can begin at step 702 where the method includes forming a pillar on an LED chip, wherein the pillar is conductive, and is formed on a conductive layer. The pillar can be formed by depositing or forming a layer of copper on a substrate of the LED chip 102 and then etching the copper layer to form the pillars. The etching can include laser etching, plasma etching, chemical etching, or mechanical etching (e.g., sandblasting, CO₂ blasting, punch outs, etc.). In some embodiments, the pillars may be comprised of a ceramic or silicate material and also be plated with various metals including one or more of copper, titanium, silver, gold, tin, or nickel. The pillars can also be terminated in a metal alloy/solder such as SAC or bismuth silver, or other leaded or lead free solder.

At 704, the method includes forming a hollow via in a substrate. The hollow vias can be formed by etching the substrate using one of the aforementioned etching techniques. The substrate can be comprised of ceramic materials such as aluminum oxide or alumina, AlN, or organic insulators like polyimide (PI) and polyphthalamide (PPA).

At 706, the method includes mounting the substrate on a submount. The substrate can be attached via solder or an adhesive. The substrate can be aligned such that the hollow vias in the substrate line up with one or more traces on the submount.

At 708, the method includes mounting the LED chip on the substrate, wherein the pillar extends into the hollow via to electrically couple with the submount. The LED chip can be attached to the substrate via solder on the tips of the pillars that forms a connection with either the conductive pads on a backside of the substrate or with the traces on the submount. Alternatively, or in addition, the hollow vias could be filled with an electrically conductive adhesive that facilitates an electrical and thermal connection between the pillars and the substrate or submount.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package, comprising
a submount;
a substrate bonded to the submount, wherein the substrate comprises a hollow via; and
an LED chip mounted to the substrate, wherein the LED chip comprises a conductive layer bonded to an active LED structure and a pillar formed on the conductive layer, wherein the pillar extends through the hollow via of the substrate, and is electrically coupled to the submount.

2. The LED package of claim 1, wherein the hollow via extends entirely through the substrate and the pillar is in direct contact with a trace on the submount.

3. The LED package of claim 1, wherein the hollow via extends partially through the substrate, and the pillar is in contact with a conductive pad on the substrate, wherein the conductive pad is in contact with the submount.

4. The LED package of claim 1, wherein the LED chip comprises a plurality of pillars formed on the conductive layer, wherein each pillar is configured to extend through a respective hollow via of the substrate.

5. The LED package of claim 4, wherein the plurality of pillars are arranged asymmetrically.

6. The LED package of claim 1, wherein the LED chip is flip-chip mounted to the substrate, and wherein the conductive layer comprises a plurality of conductive pads, each with one or more pillars formed thereon.

7. The LED package of claim 1, wherein the LED chip is a vertical geometry chip.

8. The LED package of claim 1, wherein the pillar comprises copper.

9. The LED package of claim 1, wherein a tip of the pillar is terminated in a metallic alloy.

10. The LED package of claim 1, wherein the pillar has a height between 10 μm and 200 μm and a diameter between 10 μm and 100 μm.

11. The LED package of claim 1, wherein the hollow via of the substrate comprises an electrically conductive adhesive.

12. A light-emitting diode (LED) chip, comprising:
an active LED structure;
a conductive layer bonded to the active LED structure;
a pillar formed on the conductive layer, wherein the pillar is conductive and is configured to extend through a hollow via of a substrate to electrically couple to a submount structure.

13. The LED chip of claim 12, wherein there are a plurality of pillars formed on the conductive layer, wherein each pillar is configured to extend through a respective hollow via of the substrate.

14. The LED chip of claim 13, wherein the plurality of pillars are arranged asymmetrically.

15. The LED chip of claim 12, wherein the LED chip is flip-chip mounted to the substrate, and wherein the conductive layer comprises a plurality of conductive pads, each with one or more pillars formed thereon.

16. The LED chip of claim 12, wherein the LED chip is a vertical geometry chip.

17. The LED chip of claim 12, wherein the pillar comprises copper.

18. The LED chip of claim 12, wherein a tip of the pillar is terminated in a metallic alloy.

19. The LED chip of claim 12, wherein the pillar has a height between 10 μm and 200 μm and a diameter between 10 μm and 100 μm.

20. A method for fabricating a light-emitting diode (LED) package, comprising
forming a pillar on an LED chip, wherein the pillar is conductive and is formed on a conductive layer;
forming a hollow via in a substrate;
mounting the substrate on a submount; and
mounting the LED chip on the substrate, wherein the pillar extends into the hollow via to electrically couple with the submount.
